(19) United States
(12) Patent Application Publication
(10) Pub. No.: US 2025/0107418 A1
(43) Pub. Date: Mar. 27, 2025

(54) ORGANIC LIGHT-EMITTING DISPLAY DEVICE AND METHOD FOR MANUFACTURING THE SAME

(71) Applicant: LG Display Co., Ltd., Seoul (KR)

(72) Inventors: KANGIL KIM, Seoul (KR); SUNGBIN SHIM, Yangsan-si (KR)

(73) Assignee: LG Display Co., Ltd., Seoul (KR)

(21) Appl. No.: 18/824,756

(22) Filed: Sep. 4, 2024

(30) Foreign Application Priority Data
Sep. 22, 2023 (KR) 10-2023-0127316

(51) Int. Cl. H10K 59/80; H10K 59/12; H10K 59/122

(52) U.S. Cl. CPC H10K 59/8792; H10K 59/1201; H10K 59/122

(57) ABSTRACT

An organic light-emitting display device and a method for manufacturing the same are discussed. The organic light-emitting display device includes a lower substrate having a plurality of subpixels, an anode disposed on the lower substrate, a bank provided to overlap an end portion of the anode and configured to define a light-emitting area, an organic light-emitting layer disposed on the anode and the bank, a cathode disposed on the organic light-emitting layer, an upper substrate disposed opposite to the lower substrate, a black matrix disposed on one surface of the upper substrate and protruding toward the lower substrate and defining an opening area corresponding to the light-emitting area, a color filter disposed on one surface of the upper substrate so as to correspond to the opening area, and a reflective layer disposed on a side surface of the black matrix.

### CROSS-REFERENCE TO RELATED APPLICATIONS

This application claims priority to Korean Patent Application No. 10-2023-0127316 filed on Sep. 22, 2023, in the Korean Intellectual Property Office, the entire contents of which is hereby expressly incorporated by reference into the present application.

### BACKGROUND

### Field

The present disclosure relates to an organic light-emitting display device, and more particularly, to an organic light-emitting display device, which includes a reflective layer and a black matrix, and a method of manufacturing the same.

### Discussion of the Related Art

An organic light-emitting display device (OLED) does not require a separate light source, unlike a liquid crystal display (LCD) device having a backlight. As such, the advantages of the organic light-emitting display device are that the organic light-emitting display device can be manufactured to be lightweight and thin, a process can be facilitated, and power consumption is low because the organic light-emitting display device can be operated by a low voltage.

Among other things, the organic light-emitting display device can have an autonomous light-emitting element, and layers of the organic light-emitting display device can be configured by thin organic films. Additional advantages of the organic light-emitting display device are that the organic light-emitting display device can have excellent flexibility and elasticity in comparison with other display devices and thus be implemented as a flexible display device.

In general, the organic light-emitting display device refers to a display device using an organic light-emitting element that injects electrons of a cathode and holes of an anode into a light-emitting layer. Here, the light-emitting layer emits light when excitons, which are made by coupling the injected electrons and holes, fall from an excited state to a ground state.

Meanwhile, studies are being continuously conducted on organic light-emitting display devices that adopt micro-cavities to improve luminous efficiency of the organic light-emitting display devices. The micro-cavity means that light is repeatedly reflected between two layers spaced apart from each other by an optical path length, such that light with a particular wavelength is amplified by constructive interference. In the case of a top emission type organic light-emitting display device, a micro-cavity is applied in a way in which light emitted from an organic light-emitting layer is repeatedly reflected between an anode, which includes a reflective layer, and a cathode configured by a semi-transmissive layer.

In addition, in the case of a bottom emission type organic light-emitting display device, a micro-cavity can be applied during a process in which light emitted from an organic light-emitting layer is reflected by a cathode even though the strength of the micro-cavity is lower in the bottom emission type organic light-emitting display device than in the top emission type organic light-emitting display device.

The frontal luminance increases in the organic light-emitting display device to which the micro-cavity is applied as described above. Therefore, the luminous efficiency of the organic light-emitting display device can be improved, power consumption can be reduced, and the lifespan can also be improved. However, lateral luminance can decrease to the extent that the frontal luminance is increased by the application of the micro-cavity to the organic light-emitting display device, and the decrease in the lateral luminance eventually can cause a problem in that a viewing angle decreases.

### SUMMARY OF THE DISCLOSURE

An object to be achieved by the present disclosure is to provide an organic light-emitting display device including an undercut area between a black matrix and a lower substrate to improve luminous efficiency and suppress a deterioration in lateral luminance, thereby solving a problem of a decrease in viewing angle.

Another object to be achieved by the present disclosure is to provide an organic light-emitting display device, in which a thickness of a reflective layer disposed on a side surface of a black matrix decreases as the distance from a lower substrate decreases, such that interference of the reflective layer in an opening area can be suppressed, and a wider opening area can be ensured.

Still another object to be achieved by the present disclosure is to provide a method of manufacturing an organic light-emitting display device, the method being provided to form an undercut area.

Technical problems to be addressed by the present disclosure are not limited to the aforementioned technical problems, and other technical problems, which are not mentioned above but can be clearly understood by those skilled in the art from the following descriptions, can also be addressed by the present disclosure.

The organic light-emitting display device according to an aspect of the present disclosure comprises a lower substrate comprising a plurality of subpixels, an anode disposed on the lower substrate, a bank provided to overlap an end portion of the anode and configured to define a light-emitting area, an organic light-emitting layer disposed on the anode and the bank, a cathode disposed on the organic light-emitting layer, an upper substrate disposed opposite to the lower substrate, a black matrix disposed on one surface of the upper substrate and protruding toward the lower substrate and being configured to define an opening area corresponding to the light-emitting area, a color filter disposed on one surface of the upper substrate so as to correspond to the opening area, and a reflective layer disposed on a side surface of the black matrix, wherein the black matrix comprises an undercut area through which a part of a bottom surface adjacent to the upper substrate is exposed.

A method of manufacturing an organic light-emitting display device according to another aspect of the present disclosure comprises preparing a mother substrate, and forming black matrices on the mother substrate; etching, by wet etching, the mother substrate on which the black matrices are formed, and forming the upper substrate having protruding portions by isotropically etching the mother substrate; depositing metal layers including light reflective metallic material on the upper substrate and the black matrices; applying a photoresist to surround the protruding portions of the upper substrate and at least a portion of the black matrix, and curing the photoresist; removing, by dry etching, the metal layer deposited on the upper substrate corresponding to the opening area, to form the reflective layer disposed on at least a portion of top surface and side surface of the black matrix; applying the photoresist between the black matrices and curing the photoresist to form color filters.

Other detailed matters of the example embodiments are included in the detailed description and the drawings.

According to one or more aspects of the present disclosure, the undercut area is formed on the bottom surface of the black matrix of the organic light-emitting display device, which can minimize an area of the opening area that is lost from the initially intended opening area. Therefore, it is possible to suppress the decrease in the aperture ratio, improve the aperture ratio, and improve the transmittance rate and luminance. In addition, it is possible to suppress a deterioration in exterior reflection visuality that occurs when external light is reflected by the reflective layer disposed in the opening area.

According to one or more aspects of the present disclosure, it is possible to increase the viewing angle by solving the limitation in which the luminance is degraded as the viewing angle changes toward the side surface in the organic light-emitting display device.

According to one or more aspects of the present disclosure, it is possible to minimize or address an issue in which the screens with the same color in the organic light-emitting display device are visually recognized as different color coordinates in accordance with the angles.

The effects according to the present disclosure are not limited to the above-mentioned effects, and more various effects are included in the present disclosure.

Further, other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic top plan view for explaining an organic light-emitting display device according to an embodiment of the present disclosure;

FIG. 2 is a schematic cross-sectional view taken along line I-I′ in FIG. 1;

FIG. 3 is a schematic cross-sectional view for explaining an organic light-emitting display device according to another embodiment of the present disclosure;

FIG. 4 is a schematic cross-sectional view for explaining an organic light-emitting display device according to still another embodiment of the present disclosure;

FIG. 5 is a schematic cross-sectional view for explaining an organic light-emitting display device according to a comparative example; and

FIGS. 6A to 6F are cross-sectional views for explaining an example of a method of manufacturing the organic light-emitting display device according to aspects of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, an organic light-emitting display device according to example embodiments of the present disclosure will be described in detail with reference to accompanying drawings. All the components of each display device according to all embodiments of the present disclosure are operatively coupled and configured.

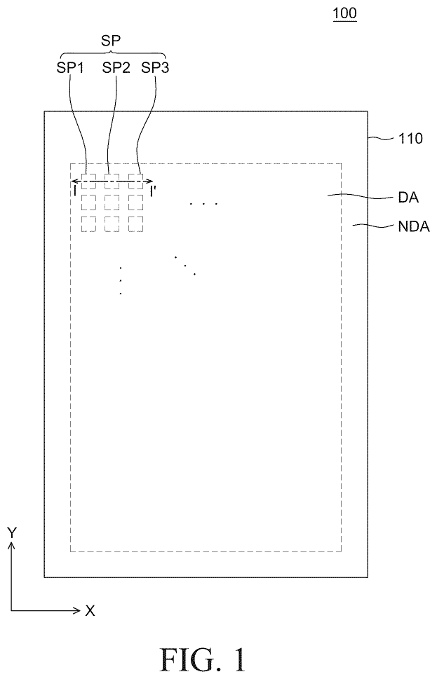

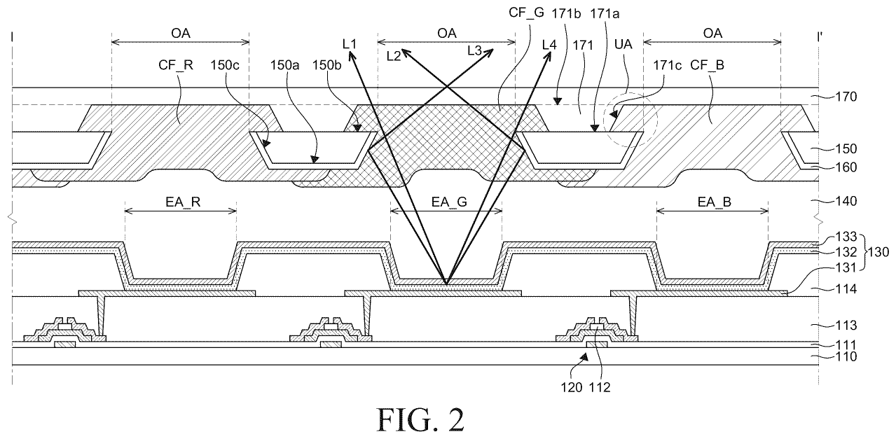

FIG. 1 is a schematic top plan view for explaining an organic light-emitting display device according to an embodiment of the present disclosure. FIG. 2 is a schematic cross-sectional view taken along line I-I′ in FIG. 1.

With reference to FIGS. 1 and 2, an organic light-emitting display device 100 according to an embodiment of the present disclosure includes a lower substrate 110, a thin-film transistor 120, an organic light-emitting element 130, a bonding layer 140, black matrices 150, reflective layers 160, color filter layers CF (CF_R, CF_G, and CF_B), and an upper substrate 170.

The organic light-emitting display device 100 according to the embodiment of the present disclosure can be configured as a top emission type organic light-emitting display device. For example, the organic light-emitting display device 100 can emit light toward the upper substrate 170. The top emission type organic light-emitting display device is configured such that light emitted from the organic light-emitting element 130 propagates to the upper substrate 170 disposed opposite to the lower substrate 110 on which the organic light-emitting element 130 is formed. In the top emission type organic light-emitting display device, a cathode 133 can be configured as a transparent electrode or a semi-transmissive electrode to allow the light emitted from the organic light-emitting element 130 to propagate to the upper substrate 170. In addition, the cathode 133 can be formed to be very thin to improve the transparency. A specific description thereof will be described below.

With reference to FIG. 1, the lower substrate 110 includes a display area DA and a non-display area NDA. The display area DA is an area in which a plurality of pixels is disposed to substantially display images. Display elements for displaying images and various driving elements for operating the display elements can be disposed in the display area DA.

The organic light-emitting display device 100 of the present disclosure can implement folding or bending. To this end, an opening or concave pattern corresponding to a folding or bending area can be formed on the lower substrate 110. Specifically, the lower substrate 110 includes an inner surface provided to face the organic light-emitting element 130, and an outer surface opposite to the inner surface. In this case, the opening or concave pattern can be a groove portion formed inward from the outer surface so that the organic light-emitting display device can be folded or bent. The opening or concave pattern can have a structure in which opening portions (or concave portions) and blocking portions (or convex portions) are continuously and alternately disposed. Therefore, the opening or concave pattern can impart flexibility to the lower substrate 110.

The display area DA can include the plurality of pixels. The plurality of pixels can be arranged in a matrix shape, and the plurality of pixels can each include a plurality of subpixels SP. Each of the subpixels SP is an element for displaying one color. The subpixel SP can be defined as an area in which a plurality of gate lines disposed in a first direction and a plurality of data lines disposed in a second direction different from the first direction intersect each other. In this case, the first direction can be a horizontal direction (e.g., X-axis direction) in FIG. 1, and the second direction can be a vertical direction (e.g., Y-axis direction) in FIG. 1. However, the present disclosure is not limited thereto. The subpixels SP each include a light-emitting area EA from which light is emitted, and a non-light-emitting area NEA from which no light is emitted. In the present specification, only the light-emitting area, from which light is emitted, is defined as the subpixel SP. The plurality of pixels can each include a first subpixel SP1, a second subpixel SP2, and a third subpixel SP3. The first subpixel SP1 can be a red pixel, the second subpixel SP2 can be a green pixel, and the third subpixel SP3 can be a blue pixel. However, the present disclosure is not limited thereto. The subpixels SP1, SP2, and SP3 each have light-emitting areas EA_R, EA_G, and EA_B. Specifically, the first subpixel SP1 can have a red light-emitting area EA_R, the second subpixel SP2 can have a green light-emitting area EA_G, and the third subpixel SP3 can have a blue light-emitting area EA_B. However, the present disclosure is not limited thereto.

The subpixels SP can each include the organic light-emitting element 130 and the driving elements. In this case, the driving element can include a switching transistor, a driving transistor, and the like. The driving element can be electrically connected to signal lines such as gate lines and data lines connected to gate drivers and data drivers disposed in the non-display area NDA.

The non-display area NDA can be disposed in a peripheral area of the lower substrate 110. The non-display area NDA can be an area in which no image is displayed. The non-display area NDA can be disposed to surround the display area DA. Various constituent elements for operating the plurality of subpixels SP disposed in the display area DA can be disposed in the non-display area NDA. For example, drive ICs, drive circuits, signal lines, flexible films, and the like, which are configured to supply signals for operating the plurality of subpixels SP, can be disposed. In this case, the drive IC can include a gate driver, a data driver, and the like. The drive IC and the drive circuit can be disposed by a gate-in-panel (GIP) method, a chip-on-film (COF) method, a tape automated bonding (TAB) method, a tape carrier package (TCP) method, a chip-on-glass (COG) method, and the like.

With reference to FIG. 2, the lower substrate 110 serves to support and protect several constituent elements of the organic light-emitting display device 100. The lower substrate 110 can be made of glass or a plastic material having flexibility. In case that the lower substrate 110 is made of a plastic material, the lower substrate 110 can be made of polyimide (PI), for example. However, the present disclosure is not limited thereto.

The thin-film transistor 120 including a gate electrode, an active layer, a source electrode, and a drain electrode is formed on the lower substrate 110. Specifically, the gate electrode is formed on the lower substrate 110, and a gate insulation layer 111 for insulating the gate electrode and the active layer is formed on the gate electrode and the lower substrate 110. The gate insulation layer 111 can be configured as a single layer made of silicon nitride (SiNx) or silicon oxide (SiOx) that is an inorganic material. Alternatively, the gate insulation layer 111 can be configured as a multilayer made of silicon nitride (SiNx) or silicon oxide (SiOx).

The active layer is formed on the gate insulation layer 111, an etch stopper 112 is formed on the active layer, and the source electrode and the drain electrode are formed on the active layer and the etch stopper 112. The source electrode and the drain electrode are electrically connected to the active layer while adjoining the active layer and formed in a partial area of the etch stopper 112. In the present specification, for convenience of description, only a thin-film driving transistor 120 is illustrated among various thin-film transistors that can be included in the organic light-emitting display device 100. In addition, in the present specification, the thin-film transistor 120 is described as having an inverted staggered structure. However, the present disclosure is not limited thereto. A thin-film transistor with a coplanar structure can be used.

An overcoating layer 113 is formed on the thin-film transistor 120. The overcoating layer 113 can be made of an insulating material, e.g., one of acrylic resin, epoxy resin, phenolic resin, polyamide-based resin, polyimide-based resin, unsaturated polyester-based resin, polyphenylene-based resin, polyphenylene sulfide-based resin, benzocyclobutene, and photoresist. However, the present disclosure is not limited thereto.

The organic light-emitting element 130 and a bank 114 are formed on the overcoating layer 113. In this case, the organic light-emitting element 130 is disposed in each of the subpixels SP1, SP2, and SP3 and includes an anode 131, an organic light-emitting layer 132, and the cathode 133. Specifically, the anode 131 configured to supply holes to the organic light-emitting layer 132 can be formed on the overcoating layer 113, and the bank 114 can be disposed around the anode 131. In this case, the bank 114 can be formed in a shape that covers an edge of the anode 131. Therefore, the bank 114 can define the light-emitting areas EA_R, EA_G, and EA_B. The organic light-emitting layer 132 can be formed on the anode 131, and the cathode 133 configured to supply electrons to the organic light-emitting layer 132 can be formed on the organic light-emitting layer 132.

FIG. 2 illustrates that the anode 131 is configured as a single layer. However, the anode 131 can include a reflective layer, and a transparent conductive layer on the reflective layer. The reflective layer of the anode 131 can be formed on the overcoating layer 113 and electrically connected to the thin-film transistor 120 through a contact hole formed in the overcoating layer 113. The reflective layer of the anode 131 can be made of a metallic material with excellent light reflectivity. For example, the reflective layer of the anode 131 can be made of a metallic material such as an alloy (Ag alloy). The transparent conductive layer of the anode 131 can be made of transparent conductive oxide (TCO) with a high work function. For example, the transparent conductive layer of the anode 131 can be made of a material such as indium tin oxide (ITO) and indium zinc oxide (IZO).

The cathode 133 can be configured as a permeable or semi-permeable conductive layer. For example, the cathode 133 can transmit a part or the entirety of the light emitted from the organic light-emitting layer 132 and allow the light to propagate to the outside. In case that the cathode 133 transmits a part of the light emitted from the organic light-emitting layer 132, another part of the light can be reflected in a direction toward the anode 131. The cathode 133 can be made of a metallic material with a low work function. In addition, the cathode 133 can be formed to have a very small thickness to ensure light transmissivity. For example, the cathode 133 can be made of a metallic material such as silver (Ag), titanium (Ti), aluminum (Al), molybdenum (Mo), an alloy of silver (Ag) and magnesium (Mg), or the like, and the metallic material can be formed to be very thin and have a thickness smaller than 500 Å. However, the present disclosure is not limited thereto.

Because the anode 131 includes the reflective layer and the cathode has light semi-permeability, a micro-cavity effect can occur in the organic light-emitting element 130. The micro-cavity means that light is repeatedly reflected between two layers spaced apart from each other by an optical path length, and the light with a particular wavelength, which implements constructive interference while corresponding to the optical path length, is amplified. As illustrated in FIG. 2, in case that the organic light-emitting display device 100 is a top emission type organic light-emitting display device, a part of the light emitted from the organic light-emitting layer 132 propagates toward the cathode 133, and another part of the light propagates toward the anode 131.

In this case, the light, which has propagated toward the anode 131, is reflected by the anode 131, and the light propagates along a path changed to be directed toward the cathode 133. As described above, a part of the light, which has propagated toward the cathode 133, passes through the cathode 133 and is discharged to the outside, and another part of the light is reflected by the cathode 133 and propagates along the path changed to be directed toward the anode 131. Therefore, the light is repeatedly reflected between the anode 131 and the cathode 133, and the light with a particular wavelength can be amplified by constructive interference based on a distance between the anode 131 and the cathode 133, i.e., a distance between a portion of the anode 131 where the light is reflected and a portion of the cathode 133 where the light is reflected.

For example, because a wavelength of a red visible ray is about 620 nm, a resonance distance in the first subpixel SP1, which corresponds to the wavelength, needs to be a multiple of about 310 nm. Therefore, a thickness of the organic light-emitting layer 132, which corresponds to a distance between the anode 131 and the cathode 133 in the first subpixel area SP1, can be set to be a multiple of about 310 nm. In addition, because a wavelength of a green visible ray is about 530 nm, a resonance distance in the second subpixel SP2, which corresponds to the wavelength, needs to be a multiple of about 265 nm. Therefore, a thickness of the organic light-emitting layer 132 in the second subpixel SP2 can be set to be a multiple of about 265 nm. In addition, because a wavelength of a blue visible ray is about 460 nm, a resonance distance in the third subpixel SP3, which corresponds to the wavelength, needs to be a multiple of about 230 nm. Therefore, a thickness of the organic light-emitting layer 132 in the third subpixel SP3 can be set to be a multiple of about 230 nm.

For example, in case that the light emitted from the organic light-emitting layer 132 is reflected by a top surface of the reflective layer of the anode 131 and a bottom surface of the cathode 133, a sum of a thickness of the organic light-emitting layer 132 and a thickness of the transparent conductive layer in the first subpixel SP1 can be set to be a multiple of about 310 nm, a sum of a thickness of the organic light-emitting layer 132 and a thickness of the transparent conductive layer in the second subpixel SP2 can be set to be a multiple of about 265 nm, and a sum of a thickness of the organic light-emitting layer 132 and a thickness of the transparent conductive layer in the third subpixel area SP3 can be set to be a multiple of about 230 nm.

In case that the resonance distance related to the light with a particular wavelength is defined as described above, the light with the corresponding wavelength, among the emitted light beams, is extracted to the outside in a state in which the amplitude of the light is increased by the constructive interference as the light is repeatedly reflected between the anode 131 and the cathode 133, whereas the light with a wavelength, which is not the corresponding wavelength, is extracted to the outside in a state in which the amplitude of the light is decreased by destructive interference as the light is repeatedly reflected between the anode 131 and the cathode 133. Therefore, the luminous efficiency related to the light with the particular wavelength corresponding to the resonance distance can be improved by implementing the micro-cavity.

In order to implement the micro-cavity as described above, a distance from the reflective layer of the anode 131 to the cathode 133 is determined by applying the resonance distance set for each of the subpixels SP1, SP2, and SP3. It is possible to define the resonance distances differently set for each of the subpixels SP1, SP2, and SP3 by adjusting the thickness of the organic light-emitting layer 132 for each of the subpixels SP1, SP2, and SP3. Alternatively, it is possible to define the resonance distances differently set for each of the subpixels SP1, SP2, and SP3 by adjusting the thickness of the transparent conductive layer on the reflective layer of the anode 131 for each of the subpixels SP1, SP2, and SP3. Alternatively, it is possible to define the resonance distance set for each of the subpixels SP1, SP2, and SP3 by adding a capping layer onto the cathode 133 for each of the subpixels SP1, SP2, and SP3 and adjusting a thickness of the capping layer.

Therefore, in the organic light-emitting display device 100 according to the embodiment of the present disclosure, a distance from the reflective layer of the anode 131 to the cathode 133 in the red light-emitting area EA_R, a distance from the reflective layer of the anode 131 to the cathode 133 in the green light-emitting area EA_G, and a distance from the reflective layer of the anode 131 to the cathode 133 in the blue light-emitting area EA_B can be different from one another. In particular, the distance relationship can be configured such that the distance from the reflective layer of the anode 131 to the cathode 133 in the red light-emitting area EA_R can be the longest, the distance from the reflective layer of the anode 131 to the cathode 133 in the green light-emitting area EA_G can be the second longest, and the distance from the reflective layer of the anode 131 to the cathode 133 in the blue light-emitting area EA_B can be the shortest.

The upper substrate 170 is disposed opposite to the lower substrate 110. The upper substrate 170 can serve to protect and support several other components of the organic light-emitting display device 100 including a color filter CF and the black matrix 150. The upper substrate 170 can be made of glass. In case that the upper substrate 170 is made of glass, a transmittance rate of the light emitted from the organic light-emitting layer 132 can be improved.

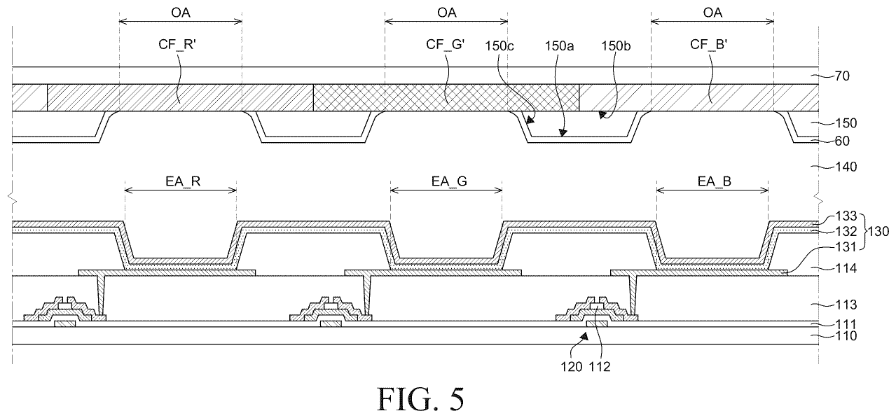

The upper substrate 170 can include a protruding portion 171 protruding toward the lower substrate 110 and formed to overlap the black matrix 150. Specifically, the black matrices 150 are formed on the upper substrate 170 and disposed to protrude toward the lower substrate 110 and define opening areas QA respectively corresponding to the light-emitting areas EA_R, EA_G, and EA_B. In addition, the black matrix 150 includes an undercut area UA through which a part of a bottom surface 150b of the black matrix 150 adjacent to the upper substrate 170 is exposed. In this case, the black matrix 150 is disposed on the protruding portion 171, and the protruding portion 171 has a structure in which a width of a top surface 171a, on which the protruding portion 171 and the black matrix 150 adjoin each other, or a bottom surface 171b, which is a rear surface of the protruding portion 171, is smaller than a width of a bottom surface 150a of the black matrix 150, such that the undercut area UA, through which a part of the bottom surface 150b of the black matrix 150 adjacent to the upper substrate 170 is exposed, is formed. As described below with reference to FIG. 5, in case that no undercut area is formed between the black matrix and the upper substrate, an end of the reflective layer enters a part of the initially intended opening area during a process of forming the reflective layer on the black matrix, which causes a problem in that the opening area is narrower than the initially intended area. Specifically, in case that a composition including a metallic material is applied onto the black matrix and cured to form the reflective layer, the composition can flow downward along the side surface of the black matrix and be disposed on a top surface of the upper substrate corresponding to the opening area. In addition, even in case that the reflective layer is formed by depositing a metallic material, the metallic material can be deposited even on the top surface of the upper substrate adjacent to the black matrix. When the end of the reflective layer enters a part of the initially intended opening area, the area of the opening area decreases, which can degrade the display performance and cause a problem in that external light is reflected by the reflective layer disposed in the opening area in a user visual field, and the visuality related to the exterior reflection deteriorates. Therefore, the undercut area UA is formed between the black matrix 150 and the upper substrate 170, which can suppress the decrease in the opening area OA by inhibiting the reflective layer 160 from entering the initially intended opening area OA during the process of forming the reflective layer 160 on the black matrix 150.

The protruding portion 171 of the upper substrate 170 can include the top surface 171a configured to adjoin the bottom surface 150b of the black matrix 150, the bottom surface 171b that is the rear surface of the protruding portion 171, and a side surface 171c configured to connect the top surface 171a and the bottom surface 171b. A width of the top surface 171a or the bottom surface 171b of the protruding portion 171 can be smaller than a width of the bottom surface 150b of the black matrix 150. For example, the side surface 171c of the protruding portion 171 is disposed inward of a side surface 150c of the black matrix 150, such that the undercut area UA can be formed between the upper substrate 170 and the black matrix 150 spaced apart from each other by the protruding portion 171.

The protruding portion 171 of the upper substrate 170 and the black matrix 150 can each have a tapered shape having a width that increases toward the upper substrate 170. In this case, the decrease in the luminance according to the viewing angle in the organic light-emitting display device 100 can be further suppressed, which can further increase the viewing angle.

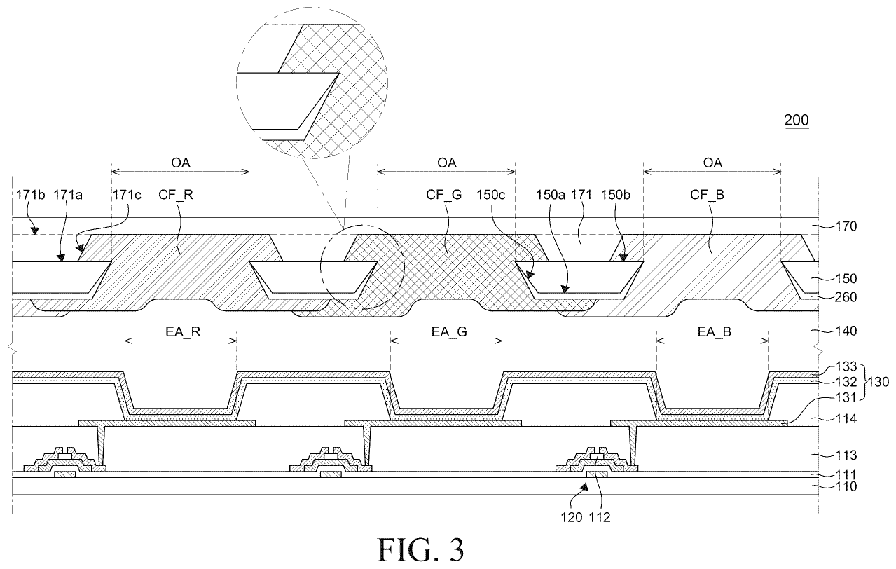

A height of the protruding portion 171 of the upper substrate 170 can be larger than a maximum thickness of the reflective layer 160 and be 0.1 μm to 1 μm or 0.5 μm to 1 μm, for example. As shown in FIG. 3, a thickness of a reflective layer 260 disposed on the side surface 150c of the black matrix 150 can decrease as the distance from the bottom surface 150b the black matrix 150 adjacent to the upper substrate 170 decreases. In this case, the maximum thickness of the reflective layer 160 means a thickness of the thickest portion when one reflective layer 160 has different thicknesses.

A photoresist PR, which can be used for the process of forming the reflective layer 160 on the black matrix 150, can more stably cover the bottom surface 150b of the black matrix 150 in the undercut area UA. Therefore, only a metal layer 160′, which is deposited even on the upper substrate 170 to form the reflective layer 160, is stably etched, which can suppress damage to the reflective layer 160 deposited on the top surface 150a or the bottom surface 150b of the black matrix 150.

The black matrix 150 can be made of an organic material. The black matrix 150 can include base resin and a black material. The base resin can be one selected from a group consisting of cardo-based resin, epoxy-based resin, acrylate-based resin, siloxane-based resin, and polyimide. However, the present disclosure is not limited thereto. The black material can be a black pigment selected from a carbon-based pigment, a metal oxide-based pigment, and an organic pigment. For example, the carbon-based pigment can be carbon black. For example, the metal oxide-based pigment can be titanium black (TiNxOy), a Cu—Mn—Fe-based black pigment, or the like. However, the present disclosure is not limited thereto. For example, the organic pigment can be selected from lactam black, perylene black, and aniline black. However, the present disclosure is not limited thereto. In addition, an RGB black pigment including a red pigment, a blue pigment, and a green pigment can be used as the black material.

Color filters CF_R, CF_G, and CF_B are disposed to respectively correspond to the opening areas OA. The undercut areas UA formed between the black matrices 150 and the upper substrate 170 can be filled with the color filters CF_R, CF_G, and CF_B. In addition, the color filters CF_R, CF_G, and CF_B, which are respectively disposed in the subpixels SP1, SP2, and SP3 adjacent to one another, can at least partially overlap one another on the top surfaces 150a of the black matrices 150 adjacent to the lower substrate 110. The color filters CF_R, CF_G, and CF_B can include a first color filter, e.g., a red color filter CF_R corresponding to the first subpixel SP1, a second color filter, e.g., a green color filter CF_G corresponding to the second subpixel SP2, and a third color filter, e.g., a blue color filter CF_B corresponding to the third subpixel SP3. The color filters CF_R, CF_G, and CF_B can each be disposed so that only one type of color filter corresponds to one of the plurality of opening areas OA. The color reproducibility can be improved in case that the color filters CF_R, CF_G, and CF_B are disposed as described above.

The color filters CF_R, CF_G, and CF_B can each independently include a transparent base resin and a chromogenic material. For example, the transparent base resin can be one selected from a group consisting of polyacrylate, polymethyl methacrylate, polyimide, polyvinyl alcohol, polyethylene, polypropylene, polystyrene, and polyethylene terephthalate. However, the present disclosure is not limited thereto. The chromogenic material means a material that absorbs light with a particular wavelength band and transmits light with the remaining wavelength bands. For example, the red color filter CF_R includes a red chromogenic material that transmits light with a red wavelength band and absorbs light with green and blue wavelength bands. For example, the red chromogenic material can be a perylene-based compound or a diketo-pyrrolopyrrole-based compound. In addition, the green chromogenic material can be a phthalocyanine-based compound. In addition, the blue chromogenic material can be a copper phthalocyanine-based compound or an anthraquinone-based compound. However, the chromogenic material is not limited thereto. Any material, which transmits light with the red, blue, and green wavelength bands, can be used without limitation.

The reflective layer 160 is disposed on the side surface 150c that connects the top surface 150a and the bottom surface 150b of the black matrix 150. In addition, the reflective layer 160 can be disposed even on the top surface 150a of the black matrix 150. Among the light beams L1, L2, L3, and L4 emitted from the organic light-emitting layer 132, the light beams L1 and L4 propagating toward a light-emitting area EA pass through the upper substrate 170 and are discharged to the outside. However, the light beams L2 and L3 propagating toward an area excluding the light-emitting area EA are absorbed by other components, such as the color filters CF_R, CF_G, and CF_B or the black matrix 150, and sometimes cannot be discharged to the outside. Therefore, the reflective layer 160 can be disposed on the side surface of the black matrix 150, such that the reflective layer 160 can reflect or scatter the light beams L2 and L3 propagating toward the area excluding the light-emitting area EA and change a path of the light to the upper substrate 170. For example, it is possible to additionally discharge the light, which has been lost by being absorbed by the other components, to the outside by means of the reflective layer 160. Therefore, the light is discharged to the area beyond a range of a viewing angle in the related art, such that the viewing angle is ensured. In addition, the amount of light discharged to the light-emitting area EA increases, such that the color reproduction range is improved.

The reflective layer 160 can include light reflective metallic material. In this case, the light reflective metallic material can include one or more metallic materials selected from a group consisting of gold (Au), platinum (Pt), silver (Ag), copper (Cu), nickel (Ni), titanium (Ti), magnesium (Mg), aluminum (Al), rhodium (Rh), and an alloy thereof that are comparatively stable metallic materials having average light reflectance of 50% or more in all wavelength band areas. The light reflective metallic material can be aluminum (Al) or silver (Ag) that is a metal having the highest light reflectivity related to light in a wavelength area corresponding to visible rays. However, the present disclosure is not limited thereto. In case that the reflective layer 160 includes the light reflective metallic material, the efficiency in reflecting or scattering the light beams L2 and L3 propagating toward the area excluding the light-emitting area EA can be improved. Therefore, the color reproduction range can be further improved.

The reflective layer 160 can be a single layer. As described below, the reflective layer 160 can be formed as a single layer on the surface of the black matrix 150 through a deposition process. In case that the reflective layer 160 is formed as a single layer, the organic light-emitting display device 100 including the reflective layer 160 can further become thinner, and the manufacturing process can be simplified.

The maximum thickness of the reflective layer 160 can be 1 μm or less, for example, 0.01 μm to 1 μm or 0.1 μm to 0.5 μm. The light reflection efficiency can be further improved in case that the thickness of the reflective layer 160 is adjusted to the above-mentioned range. In this case, the meaning of the maximum thickness of the reflective layer 160 is the same as described above.

The lower substrate 110, on which the insulation layer 111, the thin-film transistor 120, the overcoating layer 113, the bank 114, and the organic light-emitting element 130 are stacked, can be joined to the upper substrate 170, on which the black matrices 150, the reflective layers 160, and the color filters CF_R, CF_G, and CF_B are stacked, by means of the bonding layer 140. In this case, the upper substrate 170 and the lower substrate 110 can be joined so that the opening areas OA, which are defined on the upper substrate 170 by the black matrices 150, correspond to the light-emitting areas EA_R, EA_G, and EA_B defined on the lower substrate 110 by the bank 114. In addition, the upper substrate 170 and the lower substrate 110 can be joined so that the color filters CF_R, CF_G, and CF_B on the upper substrate 170 face the cathode 133 on the lower substrate 110. For example, the bonding layer 140 can be disposed between the color filters CF_R, CF_G, and CF_B and the cathode 133. The bonding layer 140 can be configured as a single layer or a plurality of layers, as necessary. However, the present disclosure is not limited thereto.

As described above, the organic light-emitting display device 100 according to the embodiment of the present disclosure includes the upper substrate 170 including the protruding portion 171, and the black matrix 150 disposed on the protruding portion 171 and having the surface on which the reflective layer 160 is formed. Therefore, it is possible to change the path of the light so that the light propagates toward the upper substrate 170 in the light-emitting area EA by reflecting or scattering the light beams L2 and L3 propagating toward the area excluding the light-emitting area EA. In addition, the path of the light, which has been lost, is changed to be directed toward the light-emitting area EA as described above, such that the amount of light emitted from the light-emitting area EA increases, and the color reproduction range is improved. Meanwhile, the organic light-emitting display device 100 according to the embodiment of the present disclosure includes the undercut area UA between the black matrix 150 and the upper substrate 170, and a part of the bottom surface 150b of the black matrix 150 is exposed through the undercut area UA. In case that the undercut area UA is formed below the black matrix 150, it is possible to improve an aperture ratio and suppress a situation in which the opening area decreases as the reflective layer 160 is disposed on the upper substrate 170, on which the black matrix 150 is not disposed, during the process of forming the reflective layer 160 on the black matrix 150. Further, the problem, in which the reflection visuality from the outside deteriorates, can be solved by the reflective layer disposed in the opening area.

FIG. 3 is a schematic cross-sectional view for explaining an organic light-emitting display device 200 according to another embodiment of the present disclosure.

With reference to FIG. 3, in the organic light-emitting display device 200 according to another embodiment of the present disclosure, a thickness of the reflective layer 260 disposed on the side surface 150c of the black matrix 150 can decrease as the distance from the bottom surface 150b of the black matrix 150 adjacent to the upper substrate 170 decreases. In addition, an end of the bottom surface 150b of the black matrix 150 can be consistent with an end of the reflective layer 260 at the side adjacent to the bottom surface 150b of the black matrix 150. Therefore, the decrease in the opening area OA caused by interference with the opening area OA of the reflective layer 260 can be suppressed, and the wider opening area OA can be ensured. In addition, the reflective layer 260 is formed so as not to overlap the opening area OA, such that the wider opening area OA can be ensured, which can further improve the transmittance rate and luminance.

The description of all the components of the organic light-emitting display device 100 according to the embodiment in FIGS. 1 and 2 can be equally applied to the description of all the components that are not described when the organic light-emitting display device 200 according to the embodiment of the present disclosure is described with reference to FIG. 3. Therefore, the description of the components identical to the components of the organic light-emitting display device 100 according to the embodiment of the present disclosure in FIGS. 1 and 2 will be omitted.

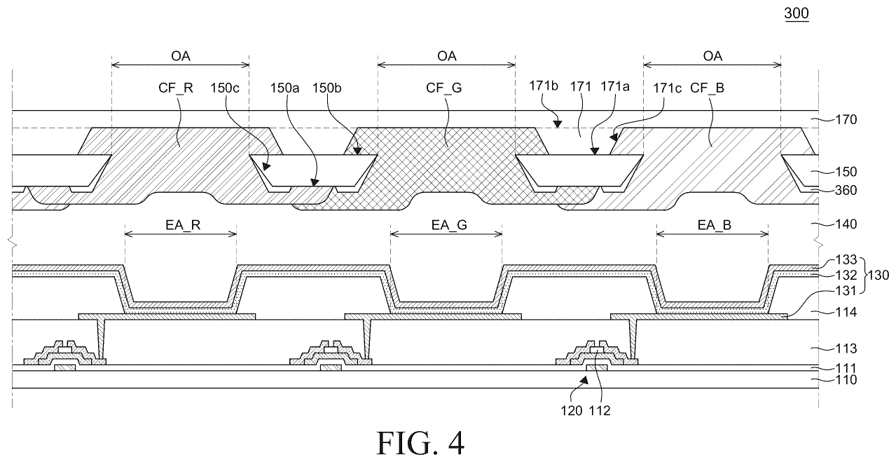

FIG. 4 is a schematic cross-sectional view for explaining an organic light-emitting display device 300 according to still another embodiment of the present disclosure.

As illustrated in FIGS. 2 and 3, in the organic light-emitting display device 100 or 200 according to the embodiment of the present disclosure, the reflective layer 160 or 260 can be disposed on the entire top surface 150a of the black matrix 150 at the side adjacent to the lower substrate 110. In addition, as illustrated in FIG. 4, a reflective layer 360 can be disposed on a part of the top surface 150a of the black matrix 150 to expose at least a part of the top surface 150a of the black matrix 150 adjacent to the lower substrate 110. Therefore, the light, which is emitted from the organic light-emitting layer 132 and propagates toward the top surface 150a of the black matrix 150, is absorbed by the exposed top surface 150a of the black matrix 150. Therefore, it is possible to suppress a color mixture that can occur when the light emitted from the organic light-emitting layer 132 is reflected by another adjacent subpixel again.

The description of all the components of the organic light-emitting display device 100 according to the embodiment in FIGS. 1 and 2 can be equally applied to the description of all the components that are not described when the organic light-emitting display device 300 according to the embodiment of the present disclosure is described with reference to FIG. 4. Therefore, the description of the components identical to the components of the organic light-emitting display device 100 according to the embodiment of the present disclosure in FIGS. 1 and 2 will be omitted.

FIG. 5 is a schematic cross-sectional view for explaining an organic light-emitting display device according to a comparative example.

With reference to FIG. 5, in the organic light-emitting display device according to the comparative example, color filter layers CF_R′, CF_G′, and CF_B′ are disposed on a upper substrate 70, the black matrices 150 are disposed on the color filter layers CF_R′, CF_G′, and CF_B′, and reflective layers 60 having shapes surrounding the black matrices 150 are disposed. For example, in the organic light-emitting display device according to the comparative example, no undercut area is formed between the black matrix 150 and an upper substrate 70. In this case, as described above, there occurs a problem in that the opening area OA is narrower than the initially intended area as an end of the reflective layer 60 enters a part of the initially intended opening area OA during the process of forming the reflective layer 60 on the black matrix 150. In addition, there occurs a problem in that the exterior reflection visuality is degraded as external light is reflected by the reflective layer 60 is disposed in the opening area OA.

Therefore, as described above with reference to FIGS. 1 to 4, in the organic light-emitting display device 100, 200, or 300 according to various embodiments of the present disclosure, the undercut area UA is formed between the black matrix 150 and the upper substrate 170, which can suppress the decrease in the opening area OA by inhibiting the reflective layer 160, 260, or 360 from entering the initially intended opening area OA during the process of forming the reflective layer 160, 260, or 360 on the black matrix 150. Therefore, the external light is reflected by the reflective layer 60 disposed in the opening area QA, which can suppress a deterioration in exterior reflection visuality.

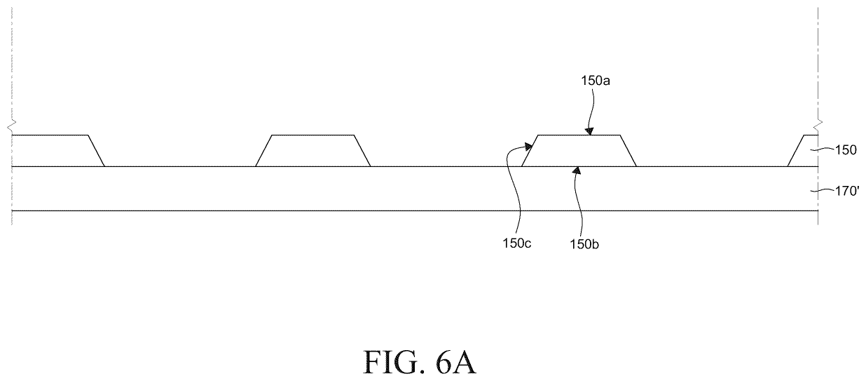

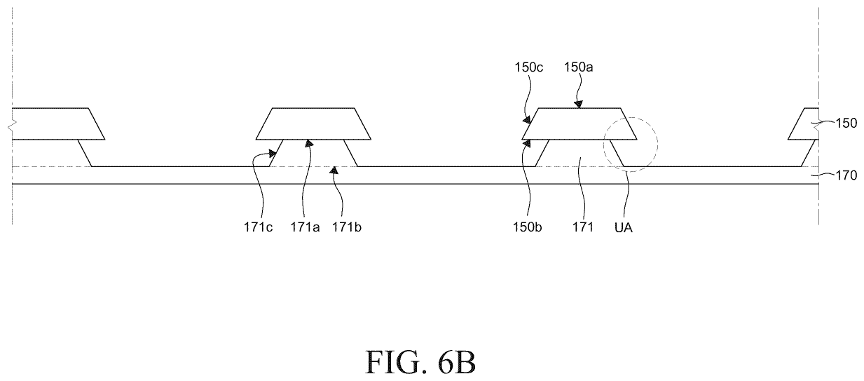

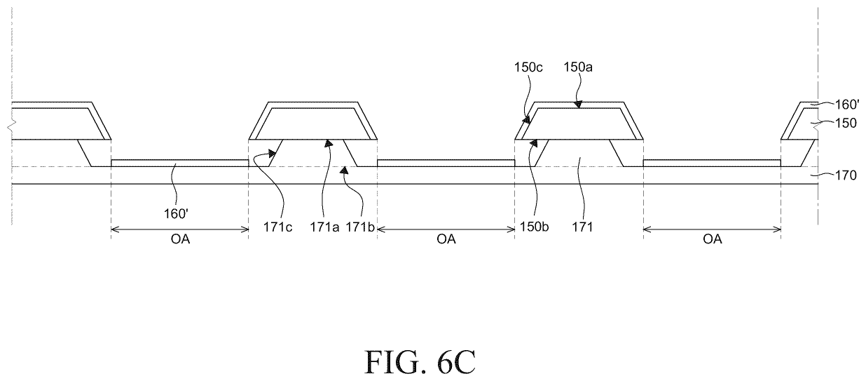

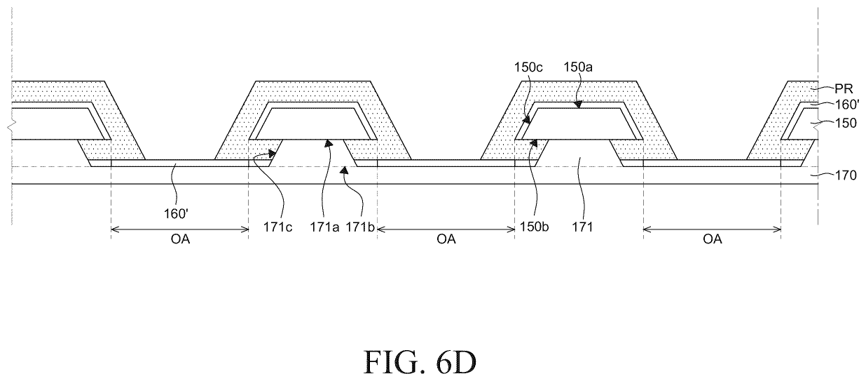

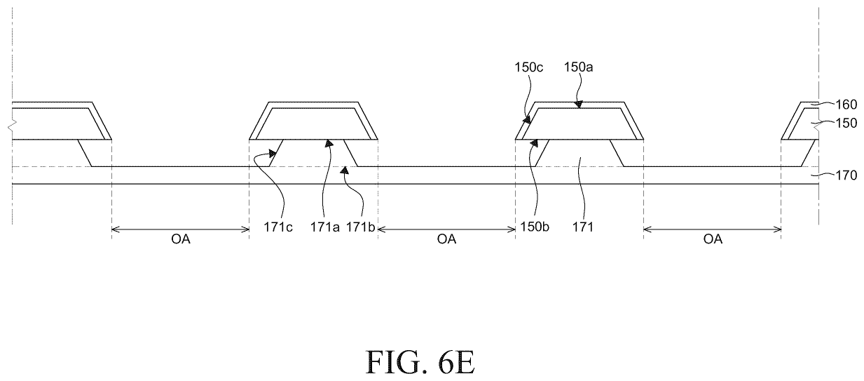

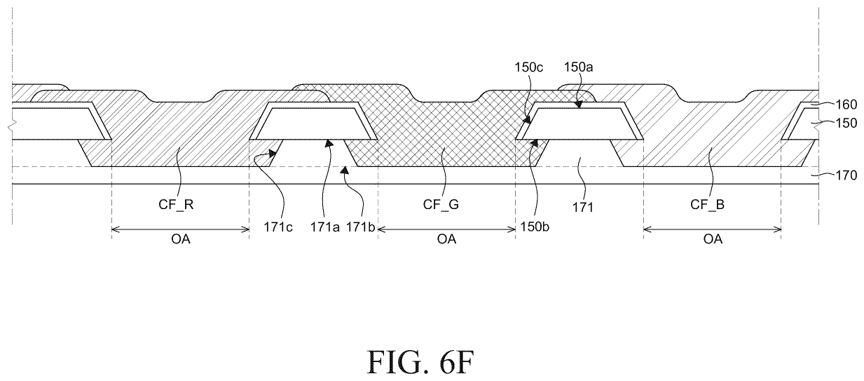

FIGS. 6A to 6F are cross-sectional views for explaining an example of a method of manufacturing the black matrix 150, the reflective layer 160, the color filter CF, and the upper substrate 170 on which are the black matrix 150, the reflective layer 160, the color filter CF among the components of the organic light-emitting display device 100 according to aspects of the present disclosure.

With reference to FIG. 6A, first, a mother substrate 170′ made of glass is prepared, and the black matrices 150 are formed on the mother substrate 170′. For example, the black matrix 150 can be patterned by a photoresist process.

With reference to FIG. 6B, the mother substrate 170′, on which the black matrices 150 are formed, is etched by wet etching. Therefore, the upper substrate 170 having the protruding portions 171 is formed by isotropically etching the mother substrate 170′ including a top surface of the mother substrate 170′, which is exposed because the black matrix 150 is not disposed, and a part of a contact surface between the black matrix 150 and the mother substrate 170′. Therefore, the undercut area UA, through which a part of the black matrix 150 is exposed, is formed between the black matrix 150 and the upper substrate 170.

With reference to FIG. 6C, metal layers 160′ including the light reflective metallic material are deposited on the upper substrate 170 and the black matrices 150. Therefore, the metal layer 160′ is deposited on the top surface 150a and the side surface 150c of the black matrix 150. In addition, the opening area OA is defined between the adjacent black matrices 150, and the metal layer 160′ is deposited even on the upper substrate 170 corresponding to the opening area OA. For example, the metal layer 160′ may not be deposited on the bottom surface 150b of the black matrix 150, the side surface 171c of the protruding portion 171, and the top surface of the upper substrate 170 in the undercut area UA. Meanwhile, FIG. 6C illustrates that the metal layer 160′ is not disposed on the top surface of the upper substrate 170 in the undercut area UA. However, the present disclosure is not limited thereto. At least a part of the metal layer 160′ can extend to be disposed on the top surface of the upper substrate 170 in the undercut area UA. In this case, the deposition can be performed by a chemical vapor deposition (CVD) process, a plasma enhanced chemical vapor deposition (PECVD) process, and the like. However, the present disclosure is not limited thereto.

With reference to FIG. 6D, the photoresist is applied to surround the protruding portion 171 of the upper substrate 170 and the black matrix 150, and the photoresist is cured by using a high-temperature plate, a furnace, or a UV curing tool. However, the present disclosure is not limited thereto.

With reference to FIG. 6E, the metal layer 160′ deposited on the upper substrate 170 corresponding to the opening area OA is removed by dry etching. Therefore, the metal layer 160′ deposited on the black matrix 150 is protected by the photoresist from the etching and maintained without being removed. Meanwhile, the metal layer 160′, which is deposited on the upper substrate 170 and is not protected by the photoresist, is removed. Therefore, the reflective layer 160 disposed on the top surface 150a and the side surface 150c of the black matrix 150 is formed.

Next, the photoresist is removed by using a tool such as an RF or microwave plasma resist stripper. However, the present disclosure is not limited thereto.

The reflective layer 160 can be formed on the side surface 150c and the top surface 150a of the black matrix 150 by the above-mentioned process.

With reference to FIG. 6F, the photoresist for forming the color filters CF_R, CF_G, and CF_B is applied between the black matrices 150 and cured. In this case, one type of color filter CF_R, CF_G, or CF_B is formed between the two adjacent black matrices 150, which suppresses a color mixture between different color filters.

The example embodiments of the present disclosure can also be described as follows:

According to an aspect of the present disclosure, there is provided an organic light-emitting display device. The organic light-emitting display device comprises a lower substrate comprising a plurality of subpixels, an anode disposed on the lower substrate, a bank provided to overlap an end portion of the anode and configured to define a light-emitting area, an organic light-emitting layer disposed on the anode and the bank, a cathode disposed on the organic light-emitting layer, an upper substrate disposed opposite to the lower substrate, a black matrix disposed on one surface of the upper substrate and protruding toward the lower substrate and being configured to define an opening area corresponding to the light-emitting area, a color filter disposed on one surface of the upper substrate so as to correspond to the opening area, and a reflective layer disposed on a side surface of the black matrix, wherein the black matrix comprises an undercut area through which a part of a bottom surface of the black matrix adjacent to the upper substrate is exposed.

The upper substrate can comprise a protruding portion protruding toward the lower substrate, and the black matrix can be disposed on the protruding portion.

The protruding portion can comprise a top surface adjacent to the bottom surface of the black matrix, a bottom surface that is a rear surface opposite to the top surface, and a side surface configured to connect the top surface and the bottom surface, and a width of the top or bottom surface of the protruding portion can be smaller than a width of the bottom surface of the black matrix.

The side surface of the protruding portion can be disposed inward of the side surface of the black matrix, and the undercut area can be formed between the upper substrate and the black matrix spaced apart from each other by the protruding portion.

The protruding portion and the black matrix each can have a tapered shape having a width that increases toward the upper substrate.

A height of the protruding portion can be larger than a maximum thickness of the reflective layer.

A thickness of the reflective layer can become thinner as s distance from the bottom surface of the black matrix being adjacent to the upper substrate decreases.

An end of the bottom surface of the black matrix can be consistent with an end of the reflective layer at a side adjacent to the bottom surface of the black matrix.

The reflective layer may not overlap the opening area.

The reflective layer can include a light reflective metallic material.

The light reflective metallic material can include aluminum or silver.

The reflective layer can be a single layer.

The reflective layer can be further disposed on a part of a top surface of the black matrix to expose at least a part of the top surface of the black matrix adjacent to the lower substrate.

The undercut area can be filled with the color filter.

The color filters respectively disposed in the adjacent subpixels can at least partially overlap each other on a top surface of the black matrix adjacent to the lower substrate.

The upper substrate can be made of glass.

According to another aspect of the present disclosure, there is provided a method of manufacturing an organic light-emitting display device according to another aspect of the present disclosure comprises preparing a mother substrate, and forming black matrices on the mother substrate; etching, by wet etching, the mother substrate on which the black matrices are formed, and forming the upper substrate having protruding portions by isotropically etching the mother substrate; depositing metal layers including light reflective metallic material on the upper substrate and the black matrices; applying a photoresist to surround the protruding portions of the upper substrate and at least a portion of the black matrix, and curing the photoresist; removing the metal layer deposited on the upper substrate corresponding to the opening area by dry etching, to form the reflective layer disposed on at least a portion of top surface and side surface of the black matrix; applying the photoresist between the black matrices and curing the photoresist to form color filters.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. An organic light-emitting display device comprising:
a lower substrate comprising a plurality of subpixels;
an anode disposed on the lower substrate;
a bank disposed to overlap an end portion of the anode and configured to define a light-emitting area;
an organic light-emitting layer disposed on the anode and the bank;
a cathode disposed on the organic light-emitting layer;
an upper substrate disposed opposite to the lower substrate;
a black matrix disposed on one surface of the upper substrate and protruding toward the lower substrate, the black matrix being configured to define an opening area corresponding to the light-emitting area;
a color filter disposed on the one surface of the upper substrate so as to correspond to the opening area; and
a reflective layer disposed on a side surface of the black matrix,
wherein the black matrix comprises an undercut area through which a part of a bottom surface of the black matrix adjacent to the upper substrate is exposed.

2. The organic light-emitting display device of claim 1, wherein the upper substrate comprises a protruding portion protruding toward the lower substrate, and the black matrix is disposed on the protruding portion.

3. The organic light-emitting display device of claim 2, wherein the protruding portion comprises:
a top surface adjacent to the bottom surface of the black matrix;
a bottom surface opposite to the top surface of the protruding portion; and
a side surface configured to connect the top surface of the protruding portion and the bottom surface of the protruding portion, and
wherein a width of the top or bottom surface of the protruding portion is smaller than a width of the bottom surface of the black matrix.

4. The organic light-emitting display device of claim 3, wherein the side surface of the protruding portion is disposed inward of the side surface of the black matrix, and the undercut area is formed between the upper substrate and the black matrix spaced apart from each other by the protruding portion.

5. The organic light-emitting display device of claim 2, wherein each of the protruding portion and the black matrix has a tapered shape having a width that increases toward the upper substrate.

6. The organic light-emitting display device of claim 2, wherein a height of the protruding portion is larger than a maximum thickness of the reflective layer.

7. The organic light-emitting display device of claim 1, wherein a thickness of the reflective layer becomes thinner as s distance from the bottom surface of the black matrix being adjacent to the upper substrate decreases.

8. The organic light-emitting display device of claim 7, wherein an end of the bottom surface of the black matrix is consistent with or corresponds to an end of the reflective layer at a side adjacent to the bottom surface of the black matrix.

9. The organic light-emitting display device of claim 8, wherein the reflective layer does not overlap with the opening area.

10. The organic light-emitting display device of claim 1, wherein the reflective layer includes a light reflective metallic material.

11. The organic light-emitting display device of claim 10, wherein the light reflective metallic material includes aluminum or silver.

12. The organic light-emitting display device of claim 10, wherein the reflective layer is a single layer.

13. The organic light-emitting display device of claim 1, wherein the reflective layer is further disposed on a part of a top surface of the black matrix to expose at least a part of the top surface of the black matrix adjacent to the lower substrate.

14. The organic light-emitting display device of claim 1, wherein the undercut area is filled with the color filter.

15. The organic light-emitting display device of claim 1, wherein the color filters respectively disposed in adjacent subpixels at least partially overlap each other on a top surface of the black matrix adjacent to the lower substrate.

16. The organic light-emitting display device of claim 1, wherein the upper substrate is made of glass.

17. The organic light-emitting display device of claim 1, wherein the anode comprises a reflective layer, and a distance from the reflective layer of the anode to the cathode is determined based on a resonance distance set for each subpixel.

18. A method of manufacturing an organic light-emitting display device, the method comprising:
preparing a mother substrate, and forming black matrices on the mother substrate;
etching, by wet etching, the mother substrate on which the black matrices are formed, and forming the upper substrate having protruding portions by isotropically etching the mother substrate;
depositing metal layers including a light reflective metallic material on the upper substrate and the black matrices;
applying a photoresist to surround the protruding portions of the upper substrate and at least a portion of the black matrix, and curing the photoresist;
removing, by dry etching, the metal layer deposited on the upper substrate corresponding to an opening area, to form the reflective layer disposed on at least a portion of top surface and side surface of the black matrix; and
applying the photoresist between the black matrices and curing the photoresist to form color filters.
